(19) United States
(12) Patent Application Publication
(10) Pub. No.: US 2026/0188197 A1
(43) Pub. Date: Jul. 2, 2026

(54) DISPLAY APPARATUS

(71) Applicant: LG Display Co., Ltd., Seoul (KR)

(72) Inventor: Dongmin LEE, Paju-si (KR)

(73) Assignee: LG Display Co., Ltd., Seoul (KR)

(21) Appl. No.: 19/424,754

(22) Filed: Dec. 18, 2025

(30) Foreign Application Priority Data
Jan. 2, 2025 (KR) 10-2025-0000283

(51) Int. Cl. G09G 3/32; H10H 29/32; H10H 29/855

(52) U.S. Cl. CPC G09G 3/32; H10H 29/32; H10H 29/8552; G09G 2320/0242; G09G 2330/021

(57) ABSTRACT

One or more aspects of the subject technology provide a display apparatus capable of preventing white color coordinate variation during low-speed driving. In one or more examples, a display apparatus includes a first subpixel including a first light emitting element configured to emit light of a first color, a first driving transistor configured to drive the first light emitting element, and a first capacitor disposed between a drain electrode and a source electrode of the first driving transistor, and a second subpixel including a second light emitting element configured to emit light of a second color, a second driving transistor configured to drive the second light emitting element, and a second capacitor disposed between a drain electrode and a source electrode of the second driving transistor. A capacitance of the first capacitor is different from a capacitance of the second capacitor.

### CROSS-REFERENCE TO RELATED APPLICATION

This application claims the benefit of and priority to Korean Patent Application No. 10-2025-0000283 filed on Jan. 2, 2025, the entire contents of which are incorporated herein by reference for all purposes.

### BACKGROUND

### 1. Technical Field

The present disclosure relates to a display apparatus, and particularly to, for example, without limitation, a display apparatus capable of preventing or reducing white color coordinate fluctuations.

### 2. Description of Related Art

The electroluminescence display apparatuses have the advantages of high brightness, low operating voltage, ultra-thinness, and freedom of shape implementation by utilizing self-luminous elements.

In an electroluminescence display apparatus, each light emitting element of the pixels constituting the display panel is independently driven by a pixel circuit including a driving transistor.

The electroluminescence display apparatus may be driven at a low drive frequency (1 Hz) to reduce power consumption.

However, when driving at low speed, the white color coordinates may fluctuate and the optical quality may deteriorate due to differences in the potential of the nodes connected to the light emitting elements due to differences in the capacitance of the light emitting elements for each red, green, and blue subpixel.

The description of related art should not be considered prior art merely because it is mentioned in or associated with this section. The description of related art includes information that describes one or more aspects of the subject technology, and the description in this section does not limit the scope of the present disclosure.

### SUMMARY

One or more aspects of the present disclosure are directed to providing a display apparatus that substantially reduce or obviate one or more problems due to limitations and disadvantages of the related art.

One of more aspects of the present disclosure provide a display apparatus capable of improving optical quality by minimizing or reducing potential fluctuations of nodes connected to light emitting elements during low-speed operation and thus preventing or reducing white color coordinate fluctuations.

One of more aspects of the present disclosure provide a display apparatus capable of achieving low power efficiency through low-speed operation.

One of more aspects of the present disclosure provide a display apparatus capable of preventing or reducing color coordinate fluctuations for different subpixels without adding a mask process.

Additional advantages and features of the disclosure will be set forth in part in the description which follows and in part will become apparent to those having ordinary skill in the art upon examination of the following or may be learned from practice of the disclosure. The technical benefits and other advantages of the disclosure may be realized and attained by the structure particularly pointed out in the written description and claims hereof as well as the appended drawings.

The display apparatus according to one embodiment of the present disclosure includes first subpixel including a first light emitting element configured to emit light of a first color, a first driving transistor configured to drive the first light emitting element, and a first capacitor disposed between a drain electrode and a source electrode of the first driving transistor, and a second subpixel including a second light emitting element configured to emit light of a second color, a second driving transistor configured to drive the second light emitting element, and a second capacitor disposed between a drain electrode and a source electrode of the second driving transistor, wherein a capacitance of the first capacitor may be different from a capacitance of the second capacitor.

The display apparatus according to one embodiment of the present disclosure further includes a third subpixel including a third light emitting element configured to emit light of a third color, a third driving transistor configured to drive the third light emitting element, and a third capacitor disposed between a drain electrode and a source electrode of the third driving transistor, wherein a capacitance of the third capacitor may be different from at least one of the first and second capacitors.

It is to be understood that both the foregoing general description and the following detailed description of the present disclosure are examples and explanatory and are intended to provide further explanation of the disclosure.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIG. 1 is a schematic diagram illustrating the configuration of a display apparatus according to one embodiment of the present disclosure.

FIG. 2 is a drawing illustrating a pixel structure of a display apparatus according to one embodiment of the present disclosure.

FIG. 3 is a drawing schematically illustrating the configuration of red, green, and blue subpixels of a display apparatus according to one embodiment of the present disclosure.

FIG. 4 is an equivalent circuit diagram illustrating the configuration of red, green, and blue subpixels of a display apparatus according to one embodiment of the present disclosure.

FIG. 5 is a plan view illustrating a layout structure of a pixel circuit in a display apparatus according to one embodiment of the present disclosure.

FIG. 6 is a cross-sectional view illustrating the structure of first to third subpixels including first to third pixel circuits illustrated in FIG. 5.

FIG. 7 is a plan view illustrating a layout structure of a pixel circuit in a display apparatus according to one embodiment of the present disclosure.

FIGS. 8A to 8C are cross-sectional views illustrating the structure of first to third subpixels including the first to third pixel circuits illustrated in FIG. 7.

FIG. 9 is a plan view illustrating a layout structure of a pixel circuit in a display apparatus according to one embodiment of the present disclosure.

FIGS. 10A to 10C are cross-sectional views illustrating the structure of first to third subpixels including the first to third pixel circuits illustrated in FIG. 9.

FIGS. 11 and 12 are tables illustrating simulation results of white color coordinate fluctuations when a display apparatus is driven at 1 Hz according to a comparative example and an embodiment.

FIG. 13 is a chromaticity diagram showing the variation in white color coordinates when a display apparatus is driven at 1 Hz according to a comparative example and an embodiment.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Advantages and features of the present disclosure, and implementation methods thereof will be clarified through the following embodiments, described with reference to the accompanying drawings. The present disclosure may, however, be embodied in different forms and should not be construed as being limited to the embodiments set forth herein. Rather, these embodiments are provided so that this disclosure will be thorough and complete, and will fully convey the scope of the present disclosure to those skilled in the art.

The shapes, sizes, ratios, angles, and numbers disclosed in the drawings for describing embodiments of the present disclosure are merely examples, and thus the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In the case in which “comprise,” “have,” and “include” described in the present disclosure are used, another part may also be present unless “only” is used. The terms in a singular form may include plural forms unless noted to the contrary. In one or more examples, unless expressly stated otherwise, an element may be one or more elements; and an element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise.

In construing an element, the element is construed as including an error region although there is no explicit description thereof.

In describing a positional relationship, for example, when the positional order is described as “on,” “above,” “below,” “beneath,” and “next,” the case of no contact therebetween may be included, unless “just” or “direct” is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It is understood that, although the terms “first,” “second,” “A,” “B,” “(a),” “(b),” and the like may be used herein to describe various elements (e.g., layers, films, components, electrodes, structures, transistors, sections, members, parts, regions, areas, portions, steps, operations, and/or the like), these elements should not be limited by these terms, for example, to any particular order, precedence, or number of elements. Further, these are not used to define the essence or basis of the elements. These terms are merely used to refer to one element separately from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

Unless stated otherwise, a source electrode may refer to a drain electrode, and vice versa.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other, and may be variously inter-operated with each other and driven technically The embodiments of the present disclosure may be carried out independently from each other, or may be carried out together in a co-dependent relationship.

Hereinafter, the aspect of the present disclosure will be described with reference to the accompanying drawings. Since a scale of each of elements shown in the accompanying drawings is different from an actual scale for convenience of description, the present disclosure is not limited to the shown scale. Further, all the components of each display apparatus, display device, and display panel according to all aspects of the present disclosure are operatively coupled and configured.

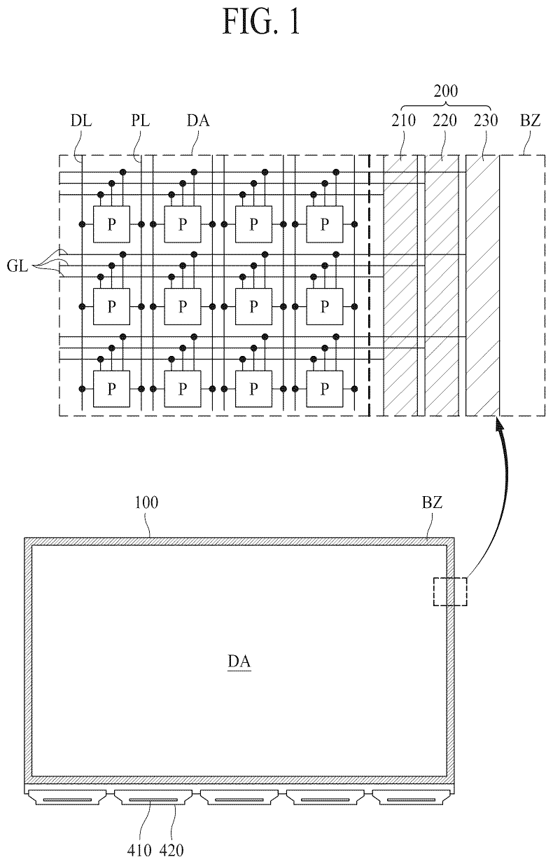

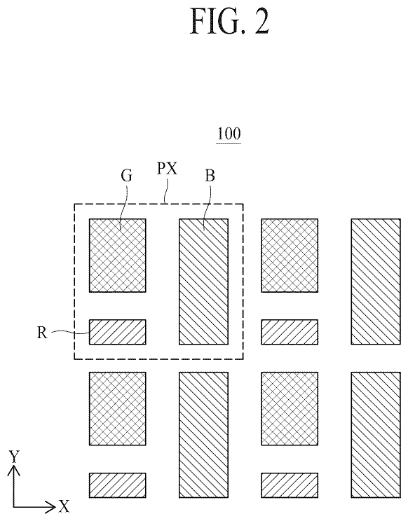

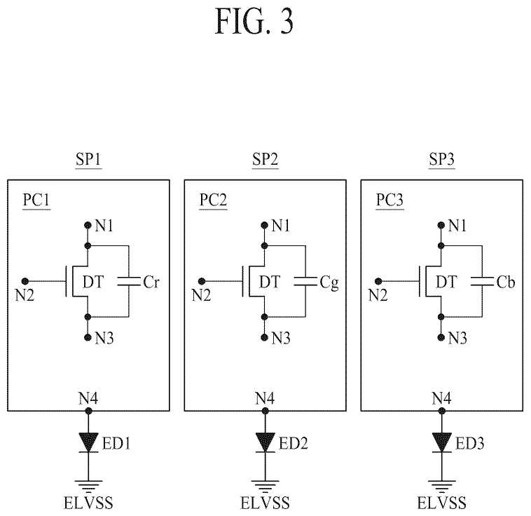

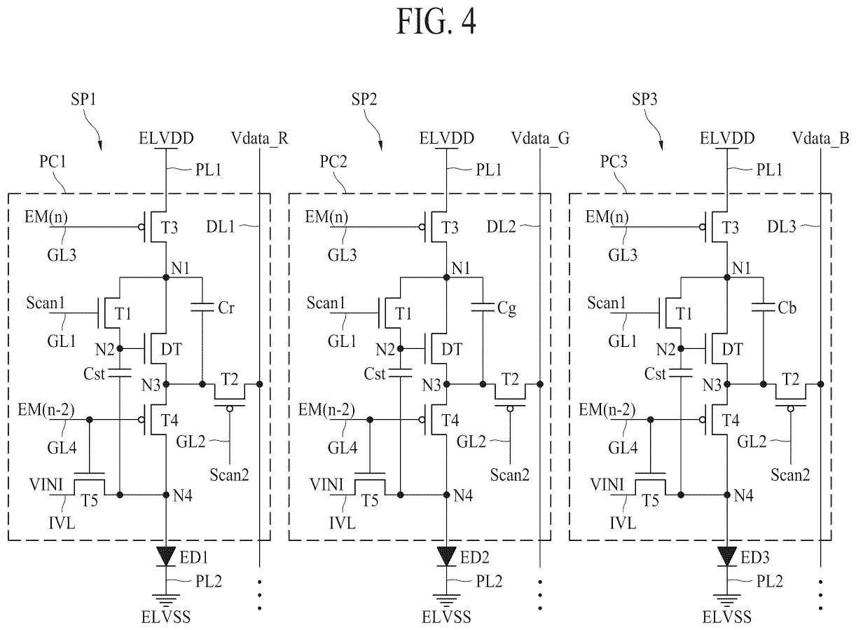

FIG. 1 is a diagram schematically illustrating a configuration of a display apparatus according to one embodiment of the present disclosure, FIG. 2 is a diagram illustrating a pixel structure of a display apparatus according to one embodiment of the present disclosure, FIG. 3 is a diagram schematically illustrating a configuration of red, green, and blue subpixels of a display apparatus according to one embodiment of the present disclosure, and FIG. 4 is an equivalent circuit diagram illustrating a configuration of red, green, and blue subpixels of a display apparatus according to one embodiment of the present disclosure.

The display apparatus according to one embodiment may be an electroluminescence display apparatus. The electroluminescence display apparatus may be any one of an organic light emitting diode (OLED) display apparatus, a quantum-dot light emitting diode (QD) display apparatus, and an inorganic light emitting diode (ILD) display apparatus.

Referring to FIG. 1, the display apparatus according to one embodiment may include a display panel 100, a gate driving circuit 200 built into the display panel 100, and a data driving circuit 410 connected to the display panel 100. The gate driving circuit 200 and the data driving circuit 410 may be expressed as a display driving circuit. The upper portion of FIG. 1 is an enlarged view of a region in a broken line box in the lower portion of FIG. 1.

The display panel 100 may be a rigid display panel or a flexible display panel capable of changing shape, such as a foldable, bendable, rollable, or stretchable display panel.

The display panel 100 may include a display area DA and a bezel area BZ corresponding to a non-display area disposed at the outer edge surrounding the display area DA.

The display panel 100 may display an image through a pixel array in which subpixels P are disposed in a matrix form in a display area DA. The pixel array of the display area DA may include a plurality of row lines composed of a plurality of subpixels P disposed in a first direction (for example, horizontal direction) and a plurality of column lines composed of a plurality of subpixels P disposed in a second direction (for example, vertical direction). In the present disclosure, the first direction and the second direction may be a horizontal direction and a vertical direction, respectively, or any two intersecting directions.

The unit pixel may include a plurality of subpixels P having different emission colors. The unit pixel may include for example first to third subpixels that emit different colors. The first to third subpixels may be red, green, and blue subpixels that emit red light, green light, and blue light, respectively, but are not limited thereto. The unit pixel may additionally include a fourth subpixel that emits white light.

Each subpixel P may include a light emitting element and a pixel circuit composed of a plurality of thin film transistors that independently drive the light emitting element. The display panel 100 may include a plurality of data lines DL, a plurality of gate lines GL, a plurality of power lines PL, and other signal lines connected to the plurality of subpixels P.

The display panel 100 according to one embodiment may further include a touch sensor array disposed in the display area DA to sense a user's touch.

The gate driving circuit 200 may be disposed in at least one bezel area BZ of the display panel 100. For example, the gate driving circuit 200 may be disposed in first and second bezel areas BZ facing each other with the display area DA interposed therebetween. The gate driving circuit 200 may be built into the display panel 100 in the form of a gate in panel (GIP) formed together with thin film transistors of the display area DA.

The gate driving circuit 200 may include a plurality of driving circuits that drive a plurality of gate lines GL. For example, the gate driving circuit 200 may include a first scan driving circuit 210 that supplies a first scan signal to each of the gate lines of a first group among the plurality of gate lines GL, a second scan driving circuit 220 that supplies a second scan signal to each of the gate lines of a second group, and a light emission control driving circuit 230 that supplies a light emission control signal to each of the gate lines of a third group. The number of gate lines GL connected to the subpixels P of each row line, the number of scan driving circuits, and the number of light emission control driving circuits may vary depending on the detailed configuration of the pixel circuit constituting each subpixel P.

The data driving circuit 410 may convert digital image data supplied from a timing controller into an analog data voltage and supply the data voltage to each of a plurality of data lines DL of the display panel 100. The data driving circuit 410 includes one or a plurality of ICs Integrated Circuits, and may be mounted on each circuit film 420 and electrically connected to a pad area disposed in a bezel area BZ of the display panel 100 through an anisotropic conductive film ACF. The circuit film 420 may be any one of a COF (Chip On Film), an FPC (Flexible Printed Circuit), and an FFC (Flexible Flat Cable).

The thin film transistors included in the driving circuit including the gate driving circuit 200 disposed in the display area DA and the bezel area BZ of the display panel 100 may include any one of a polysilicon semiconductor, an amorphous silicon semiconductor, and an oxide semiconductor. In one embodiment, the thin film transistors of the display panel 100 may include at least any one of a low temperature polysilicon (LTPS) transistor and an oxide transistor using a metal-oxide semiconductor.

The display apparatus according to one embodiment may be driven at a first driving frequency (for example, 60 Hz) or may be driven at a second driving frequency (for example, 1 Hz) to reduce power consumption. In the present disclosure, the first driving frequency and the second driving frequency may be, for example, 60 Hz and 1 Hz, respectively, but are not limited thereto.

The display apparatus driven at the first driving frequency (60 Hz) may be driven including first to 60th refresh frames that charge a new data voltage to the plurality of subpixels P of the display panel 100 for each frame period during one second.

The display apparatus driven at the second driving frequency (1 Hz) may be driven as a refresh frame for a first frame period of one second, and as an anode reset frame for maintaining a light emitting period and resetting only a fourth node connected to an anode electrode of the light emitting element to an initialization voltage VINI for the second to 60th frame periods of the one second.

The display apparatus according to one embodiment may vary the initialization voltage VINI in the anode reset frame period to compensate for a difference in luminance when the driving frequency varies between 60 Hz and 1 Hz.

Referring to FIG. 2, a display panel 100 according to one embodiment may include the pixel matrix in which unit pixels PX including red, green, and blue subpixels R, G, and B are repeatedly disposed in the first direction X and the second direction Y. The green subpixel G and the red subpixel R may be disposed adjacent to each other in the second direction Y, and the blue subpixel B may be disposed adjacent to the green subpixel G and the red subpixel R in the first direction X, but is not limited to this arrangement structure.

The red, green, and blue subpixels R, G, and B may each have a light emitting region in which each light emitting element emits light, and the remaining region may be a non-light emitting region. A black matrix may be placed in the non-light emitting region.

Among the red, green, and blue subpixels R, G, and B, the light emitting area (aperture ratio) of the blue light emitting element of the blue subpixel B may be the largest in consideration of the efficiency and lifespan of the blue light emitting element. The light emitting area (aperture ratio) of either the red light emitting element of the red subpixel R or the green light emitting element of the green subpixel G may be smaller or the smallest. In one embodiment, the light emitting area of the red light emitting element of the red subpixel R may be smaller than the light emitting area of the green light emitting element of the green subpixel G. Accordingly, in one embodiment, the capacitance of the red light emitting element of the red subpixel R may be the smallest, and the capacitance of the blue light emitting element of the blue subpixel B may be the largest.

Referring to FIG. 3, the first to third subpixels SP1, SP2, and SP3 according to one embodiment may include first to third light emitting elements ED1, ED2, and ED3 and first to third pixel circuits PC1, PC2, and PC3 that independently drive the first to third light emitting elements ED1, ED2, and ED3. Each of the first to third pixel circuits PC1, PC2, and PC3 may include a driving transistor DT connected to the first to third nodes N1, N2, and N3. Each of the first to third pixel circuits PC1, PC2, and PC3 may include first to third capacitors Cr, Cg, and Cb connected between the first and third nodes N1 and N3 of the driving transistor DT. The first to third capacitors Cr, Cg, and Cr may have different capacitances, or at least two of them may have different capacitances.

The first to third subpixels SP1, SP2, and SP3 may be red, green, and blue subpixels, respectively, and the first to third light emitting elements ED1, ED2, and ED3 may be red, green, and blue light emitting elements, respectively. For example, in one embodiment, the capacitance of the third capacitor Cb of the blue subpixel SP3 may be greater than the capacitance of the second capacitor Cg of the green subpixel SP2.

When the light emitting area (capacitance) of the red light emitting element ED1 is the smallest, the capacitance of the first capacitor Cr of the red subpixel SP1 may be the smallest, and the capacitances of the second and third capacitors Cg and Cb of the green and blue subpixels SP2 and SP3 may be larger than the capacitance of the first capacitor Cr.

Accordingly, even if the capacitance of the red light emitting element ED1 is the smallest, by increasing the capacitance of the second and third capacitors Cg and Cb of the green and blue subpixels SP2 and SP3, the potential of the node N4 connected to the anode electrodes of the red, green, and blue light emitting elements ED1, ED2, and ED3 may be similarly varied in the anode reset frame section during 1 Hz low-speed driving, thereby preventing or reducing variation in the white color coordinates.

Referring to FIG. 4, each of the pixel circuits PC1, PC2, and PC3 of the first to third subpixels SP1, SP2, and SP3 may include a driving thin film transistor DT and a plurality of thin film transistors T1 to T5 and a storage capacitor Cst.

Each of the thin film transistors DT and T1 to T5 of each of the pixel circuits PC1, PC2, and PC3 may be a thin film transistor using any one of a polysilicon semiconductor, an amorphous silicon semiconductor, and an oxide semiconductor. In one embodiment, each of the thin film transistors DT and T1 to T5 of each of the pixel circuits PC1, PC2, and PC3 may be configured as a P-type polysilicon transistor. In one embodiment, each of the thin film transistors DT and T1 to T5 of each of the pixel circuits PC1, PC2, and PC3 may be configured as an N-type oxide transistor. In one embodiment, each of the thin film transistors DT and T1 to T5 of each of the pixel circuits PC1, PC2, and PC3 may be configured by mixing a P-type polysilicon transistor and an N-type oxide transistor.

In each of the pixel circuits PC1, PC2, and PC3 according to one embodiment, the second, third, and fourth thin film transistors T2, T3, and T4 may be configured as P-type LTPS (Low-Temperature Polycrystalline Silicon) transistors having high mobility. In each of the pixel circuits PC1, PC2, and PC3 according to one embodiment, the driving transistor DT and the first and fifth thin film transistors T1 and T5 may be configured as N-type oxide transistors having a smaller off-state current (leakage current) than the LTPS transistors.

The first to third subpixels SP1, SP2, and SP3 disposed in the Nth (N is a positive integer) row line may be connected to first to fourth gate lines GL1 to GL4 disposed in the Nth row line, and may be connected to a data line DL (which, in some embodiments, may be referred to as DL1, DL2, DL3 respectively, for different subpixels), first and second power lines PL1 and PL2, and an initialization voltage line IVL.

The subpixels SP1, SP2, and SP3 may be driven to include an initialization period, a sampling period, and a light emission period for each frame.

The first thin film transistor (T1, sampling transistor) is controlled by the first gate line GL1 and may be configured to connect a second node N2 to which a gate electrode of the driving transistor DT is connected and a first node N1 to which a drain electrode (second electrode) of the driving transistor DT is connected. The first transistor T1 may connect the gate electrode and the drain electrode of the driving transistor DT in a diode structure during the initialization period and the sampling period in response to a first scan signal Scan1 of the first gate line GL1. The first thin film transistor T1 composed of an N-type oxide transistor may be turned on by a gate high voltage (gate-on voltage) of the first scan signal Scan1 and may be turned off by a gate low voltage (gate off voltage) of the first scan signal Scan1.

The second thin film transistor (T2, switching transistor) is controlled by the second gate line GL2 and may be configured to connect the data line DL and a third node N3 connected to a source electrode (first electrode) of the driving transistor DT. The second thin film transistor T2 may apply a data voltage Vdata (which, in some embodiments, may be referred to as Vdata _R, Vdata _G, Vdata _B, respectively, for different subpixels) supplied through the data line DL to the driving transistor DT during the sampling period in response to a second scan signal Scan2 of the second gate line GL2. The second thin film transistor T2 composed of a P-type LTPS transistor may be turned on by a gate low voltage (gate on voltage) of the second scan signal Scan2 and may be turned off by a gate high voltage (gate off voltage) of the second scan signal Scan2.

The third thin film transistor (T3, operation control transistor) is controlled by the third gate line GL3 and may be configured to connect the first power line PL1 supplying a high potential power voltage ELVDD and the first node N1 of the driving transistor DT. The third thin film transistor T3 may apply the high potential power voltage ELVDD supplied through the first power line PL1 to the driving transistor DT during the initialization period and the light emission period in response to a second light emission control signal EM(n) supplied through the third gate line GL3. The third thin film transistor T3, which is composed of a P-type LTPS transistor, may be turned on by a gate low voltage (gate on voltage) of the second light emission control signal EM(n) and may be turned off by a gate high voltage (gate off voltage) of the second light emission control signal EM(n).

The fourth thin film transistor (T4, light emitting control transistor) is controlled by the fourth gate line GL4 and may be configured to connect the third node N3 of the driving transistor DT and the fourth node N4 connected to the anode electrode of the light emitting element ED (which, in some embodiments, may be referred to as ED1, ED2, ED3, respectively, for different subpixels). The fourth thin film transistor T4 may connect the driving transistor DT and the anode electrode of the light emitting element ED during the light emitting period in response to the first light emitting control signal EM(n-2) of the fourth gate line GL4. The fourth thin film transistor T4, which is composed of a P-type LTPS transistor, may be turned on by a gate low voltage (gate on voltage) of the first light emitting control signal EM(n-2) and may be turned off by a gate high voltage (gate off voltage) of the first light emitting control signal EM(n-2).

The fifth thin film transistor (T5, initialization transistor) is controlled by the fourth gate line GL4 and may be configured to connect the initialization voltage line IVL supplied with an initialization voltage VINI and the fourth node N4 connected to the anode electrode of the light emitting element ED. The fourth thin film transistor T4 may apply the initialization voltage VINI to the anode electrode of the light emitting element ED during the initialization period and the sampling period excluding the light emitting period, in response to the first emission control signal EM(n-2) of the fourth gate line GL4. The initialization voltage VINI may be expressed as a reference voltage. The fifth thin film transistor T5 composed of an N-type oxide transistor may share the same first emission control signal EM(n-2) as the fourth thin film transistor T4 composed of a P-type LTPS transistor. In contrast to the fourth thin film transistor T4, the fifth thin film transistor T5 may be turned on by the gate high voltage (gate on voltage) of the first light emission control signal EM(n-2) and turned off by the gate low voltage (gate off voltage).

In this way, by having the fourth thin film transistor T4 and the fifth thin film transistor T5 share the first light emission control signal EM(n-2), the display apparatus according to one embodiment can reduce the number of scan driving circuits.

The storage capacitor Cst is connected between the second node N2 and the fourth node N4, and may hold the difference voltage (Vdata+Vth−VINI) between the compensated data voltage (Vdata+Vth) and the initialization voltage VINI as a target voltage by charging the threshold voltage Vth of the driving transistor DT during the sampling period, and may apply the held target voltage to the driving transistor DT during the light emission period.

The driving transistor DT may have the gate electrode connected to the second node N2, the source electrode (first electrode) connected to the third node N3, and the drain electrode (second electrode) connected to the first node N1. The driving transistor DT may be configured to control current according to a target voltage held in the storage capacitor Cst, supply current to the light emitting element ED through the fourth thin film transistor T4, and drive the light emitting element ED, and may adjust the brightness of the light emitting element ED according to the amount of current.

Each of the light emitting elements ED1, ED2, and ED3 may have the anode electrode connected to the third node N3 of the driving transistor DT via the fourth thin film transistor T4, a cathode electrode connected to the second power line PL2 to which a low potential power supply voltage ELVSS is applied, and a light emitting stack between the anode electrode and the cathode electrode. Each of the light emitting elements ED1, ED3, and ED4 may generate light with a brightness proportional to the amount of current supplied from the driving transistor DT via the fourth thin film transistor T4.

Each of the first to third pixel circuits PC1, PC2, and PC3 may include first to third capacitors Cr, Cg, and Cb connected between the first and third nodes N1 and N3 of the driving transistor DT. The first to third capacitors Cr, Cg, and Cb may have different capacitances, or at least two of them may have different capacitances. The capacitance of the first capacitor Cr of the red subpixel SP1 may be the smallest, and the capacitances of the second and third capacitors Cg and Cb of the green and blue subpixels SP2 and SP3 may be larger than the capacitance of the first capacitor Cr. For example, the third capacitor Cb of the blue subpixels SP3 may be the largest.

Accordingly, when driving at a low speed of 1 Hz, the fourth node N4 of the red light emitting element ED1 with a small capacitance in the first subpixel SP1 may experience a large potential fluctuation due to the first capacitor Cr of the driving transistor DT. But in the second and third subpixels SP2 and SP3, the capacitance of the second and third capacitors Cg and Cb of the driving transistor DT may be greater than the first capacitance of the first capacitor Cr of the driving transistor DT in the first subpixel SP1, thereby increasing the potential fluctuation of the fourth node N4 of each of the green light emitting element ED2 and the blue light emitting element ED3 similarly to the potential fluctuation of the fourth node N4 of the red light emitting element ED1.

Therefore, when driving at the low speed of 1 Hz, it is possible to prevent or reduce white color coordinate fluctuations due to differences in potential fluctuations of the fourth nodes N4 of the red, green, and blue light emitting elements ED1, ED2, and ED3.

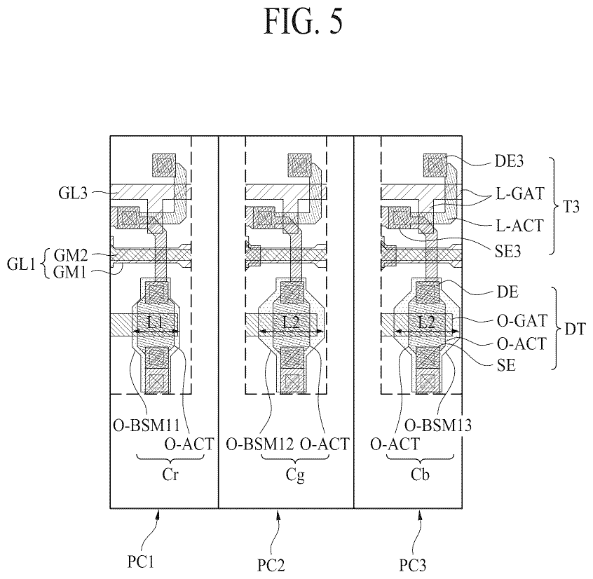

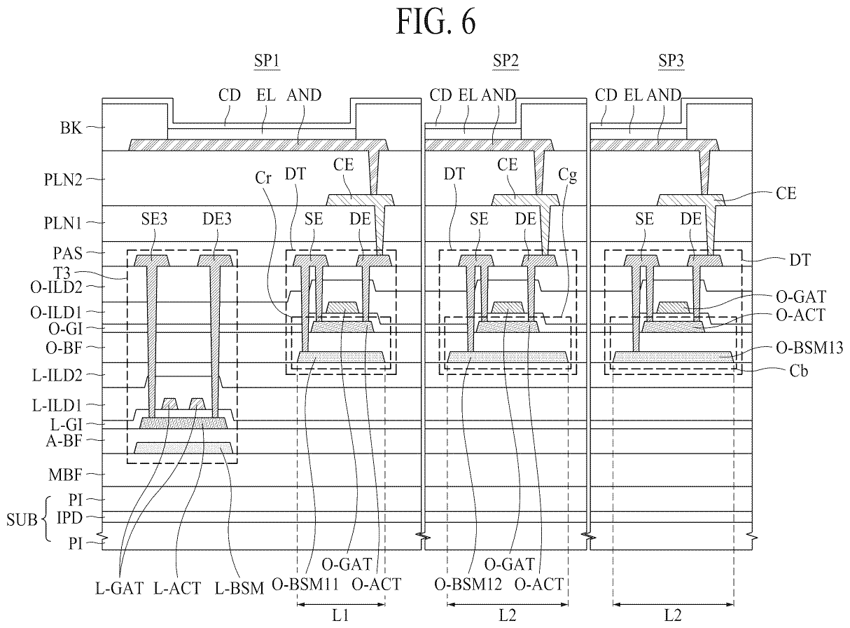

FIG. 5 is a plan view illustrating a layout structure of a pixel circuit in a display apparatus according to one embodiment of the present disclosure, and FIG. 6 is a cross-sectional view illustrating the structure of first to third subpixels including first to third pixel circuits illustrated in FIG. 5, respectively.

The layout structure of the pixel circuits PC1, PC2, and PC3 of the first to third subpixels illustrated in FIG. 5 is an example of the layout of a first light shielding metal layer, a first active layer, a first gate metal layer, a second light shielding metal layer, a second active layer, a second gate metal layer, and a first source/drain metal layer disposed on a circuit element layer of a display panel, and the layout of the second source/drain metal layer of the circuit element layer and the light emitting element layer disposed on the circuit element layer are omitted.

Referring to FIG. 5, each of the pixel circuits PC1, PC2, and PC3 includes the driving transistor DT and the plurality of thin film transistors T1 to T5 and the storage capacitor Cst as shown in FIG. 4, and may include the first to third capacitors Cr, Cg, and Cb of the driving transistor DT, respectively.

Referring to FIGS. 5 and 6, the first to third pixel circuits PC1, PC2, and PC3 of the first to third subpixels SP1, SP2, and SP3 each represent the third thin film transistor T3 which is an LTPS transistor, the driving transistor DT which is an oxide transistor, and the first to third capacitors Cr, Cg, and Cb.

Referring to FIG. 6, the first to third subpixels SP1, SP2, and SP3 according to one embodiment may include a circuit element layer including the pixel circuit PC1, PC2, and PC3 (as shown in FIG. 5) disposed on a substrate SUB, and a light emitting element layer including a light emitting element ED1, ED2, and ED3 (as shown in FIG. 4) disposed on the circuit element layer.

The substrate SUB may include a first substrate PI, an interlayer dielectric layer IPD, and a second substrate PI. The first substrate PI and the second substrate PI may include glass or a flexible polymer resin. The interlayer dielectric layer IPD may include an inorganic insulating material. A multi-buffer layer MBF may be disposed on the substrate SUB. The multi-buffer layer MBF may include an inorganic insulating material.

The third thin film transistor T3 may be disposed to overlap the third gate line GL3, as shown in FIG. 5.

The third thin film transistor T3 may include a first light shielding electrode L-BSM disposed on the multi-buffer layer MBF, a first active buffer layer A-BF covering the first light shielding electrode L-BSM, a first active layer L-ACT disposed on the first active buffer layer A-BF, a first gate insulating layer L-GI covering the first active layer L-ACT, and a first gate electrode L-GAT disposed on the first gate insulating layer L-GI. The first active layer L-ACT may include LTPS. The third thin film transistor T3 may be connected to the first active layer L-ACT through a plurality of contact holes penetrating a plurality of first interlayer insulating layers L-ILD1 and L-ILD2, a second active buffer layer O-BF, a second gate insulating layer O-GI, and a plurality of second interlayer insulating layers O-ILD1 and O-ILD2 stacked on the first gate electrode L-GAT, and may include a source electrode SE3 and a drain electrode DE3 disposed on a 2-2nd interlayer insulating layer O-ILD2. The third thin film transistor T3 may be formed in a dual gate structure.

The driving thin film transistor DT may include a second light shielding electrode O-BSM11 disposed on a 2-1st interlayer insulating layer L-ILD2, a second active buffer layer O-BF covering the second light shielding electrode O-BSM11, a second active layer O-ACT disposed on the second active buffer layer O-BF, the second gate insulating layer O-GI covering the second active layer O-ACT, and a second gate electrode O-GAT disposed on the second gate insulating layer O-GI. The second active layer O-ACT may include a metal oxide semiconductor. A driving thin film transistor DT may include the plurality of second interlayer insulating layers O-ILD1 and O-ILD2 stacked on the second gate electrode O-GAT, a plurality of contact holes penetrating the plurality of second interlayer insulating layers O-ILD1 and O-ILD2, and a source electrode SE and a drain electrode DE disposed on the 2-2nd interlayer insulating layer O-ILD2. The source electrode SE may be connected to the second light shielding electrode O-BSM11 through a contact hole penetrating the second active buffer layer O-BF, the second gate insulating layer O-GI, and the plurality of second interlayer insulating layers O-ILD1 and O-ILD2.

The first gate line GL1 may be disposed between the third thin film transistor T3 and the driving transistor DT, as shown in FIG. 5. The first gate line GL1 may have a double structure in which a first gate metal layer GM1 disposed on the first gate insulating layer L-GI and a second gate metal layer GM2 disposed on the second gate insulating layer O-GI overlap each other.

In each of the first to third pixel circuits PC1, PC2, and PC3, each of the first to third capacitors Cr, Cg, and Cb of the driving transistor DT may be formed in an overlapping structure of each of second light shielding electrodes O-BSM11, O-BSM12, and O-BSM13 and the second active layer O-ACT.

The first capacitor Cr of the first pixel circuit PC1 may be connected to the source electrode SE and the drain electrode DE of the driving transistor DT while overlapping with the driving transistor DT of the first pixel circuit PC1. The first capacitor Cr may be formed in a structure in which the second light shielding electrode O-BSM11 and the second active layer O-ACT of the driving transistor DT overlap with the second active buffer layer O-BF therebetween.

The second capacitor Cg of the second pixel circuit PC2 may be connected to the source electrode SE and the drain electrode DE of the driving transistor DT while overlapping with the driving transistor DT of the second pixel circuit PC2. The second capacitor Cg may be formed in a structure in which the second light shielding electrode O-BSM12 of the driving transistor DT and the second active layer O-ACT overlap with the second active buffer layer O-BF therebetween.

The third capacitor Cb of the third pixel circuit PC3 may be connected to the source electrode SE and the drain electrode DE of the driving transistor DT while overlapping with the driving transistor DT of the third pixel circuit PC3. The third capacitor Cb may be formed in a structure in which the second light shielding electrode O-BSM13 and the second active layer O-ACT of the driving transistor DT overlap with the second active buffer layer O-BF therebetween.

The area of each of the second light shielding electrodes O-BSM12 and O-BSM13 of the second and third capacitors Cg and Cb may be disposed to be larger than the area of the second light shielding electrode O-BSM11 of the first capacitor Cr. For example, the area of the second light shielding electrode O-BSM13 of the third capacitor Cb may be the largest.

The second light shielding electrode O-BSM11 of the first capacitor Cr may have a first width L1, and each of the second light shielding electrodes O-BSM12 and O-BSM13 of the second and third capacitors Cg and Cb may have a second width L2 greater than the first width L1. According to further embodiment of the disclosure, the second light shielding electrodes O-BSM12 and O-BSM13 of the second and third capacitors Cg and Cb may also have different widths from each other. For example, the width of the second light shielding electrode O-BSM13 of the third capacitors Cb may be the largest.

Accordingly, each of the second and third capacitances of the second and third capacitors Cg and Cb of the second and third pixel circuits PC2 and PC3 may be greater than the first capacitance of the first capacitor Cr of the first pixel circuit PC1.

A passivation layer PAS and a first planarization layer PLN1 may be disposed on the driving transistor DT. A connection electrode CE may be formed as a second source/drain metal layer on the first planarization layer PLN1. The connection electrode CE may be connected to the driving transistor DT through a contact hole penetrating the passivation layer PAS and the first planarization layer PLN1.

A second planarization layer PLN2 may be disposed on the connecting electrode CE, and a light emitting element layer may be disposed on the second planarization layer PLN2.

The light emitting element layer may include an anode electrode AND, a light emitting stack EL, and a cathode electrode CD stacked on the second planarization layer PLN2, and may include a bank insulating layer BK that provides a light emitting area in which the light emitting stack EL is disposed on the anode electrode AND.

The bank insulation layer BK may include a black material, a light shield material, and a light absorbing material. The bank insulation layer BK may include a material that absorbs a specific wavelength. The bank insulation layer BK may be configured with a structure in which at least two different colored color filters among a red color filter, a green color filter, and a blue color filter are stacked.

The anode electrode AND may be connected to the connecting electrode CE through a contact hole penetrating the second planarization layer PLN2. The anode electrode AND may be formed with a structure of multiple conductive layers having high reflectivity.

The bank insulating layer BK covering an end of the anode electrode AND may be disposed on the anode electrode AND. A light emitting stack EL may be formed in an opening of the bank insulating layer BK. The light emitting stack EL may be formed by stacking a hole control layer, a light emitting layer, and an electron control layer in that order or in the reverse order. The hole control layer may include at least a hole transport layer among a hole injection layer and a hole transport layer, and the electron control layer may include at least an electron transport layer among an electron transport layer and an electron injection layer. A light emitting stack EL may include a plurality of light emitting stacks, and at least one charge generation layer disposed between two light emitting stacks among the plurality of light emitting stacks.

The cathode electrode CD may be a common electrode disposed on the light emitting stack EL and connected along the surface of the bank insulating layer BK. The cathode electrode CD may be formed of a conductive material or a semi-transparent conductive material with high light transmittance. A capping layer may be further disposed on the cathode electrode CD to enhance the optical resonance and light emission efficiency of the light emitting element.

An encapsulating layer is disposed on the light emitting element layer to seal the light emitting element layer, thereby preventing moisture or oxygen from penetrating into the light emitting element and covering particles to prevent movement. In one embodiment, a touch sensor array including a plurality of touch electrodes may be further disposed on the encapsulating layer. A color filter array including a color filter and a black matrix, or a lens array, may be further disposed on the touch sensor array.

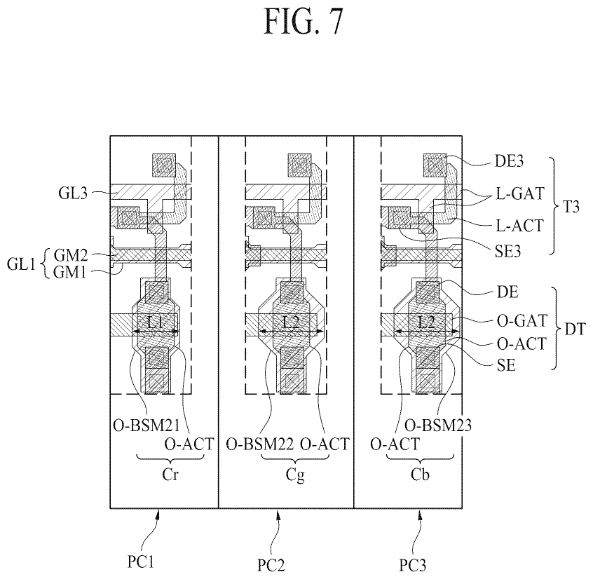

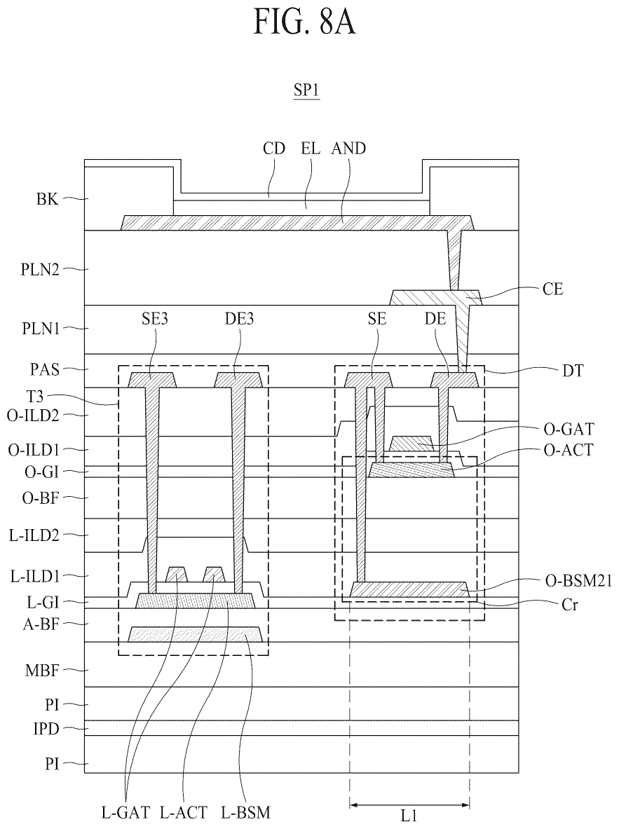

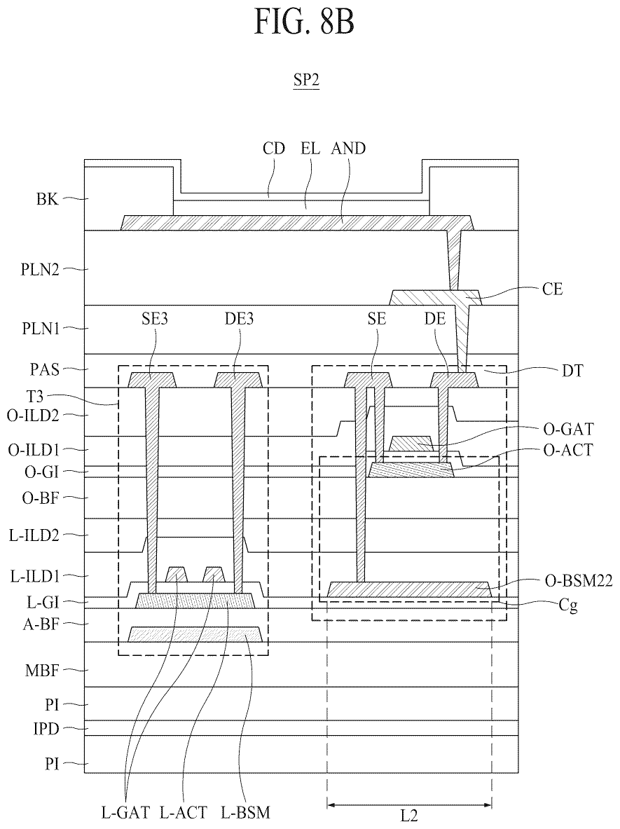

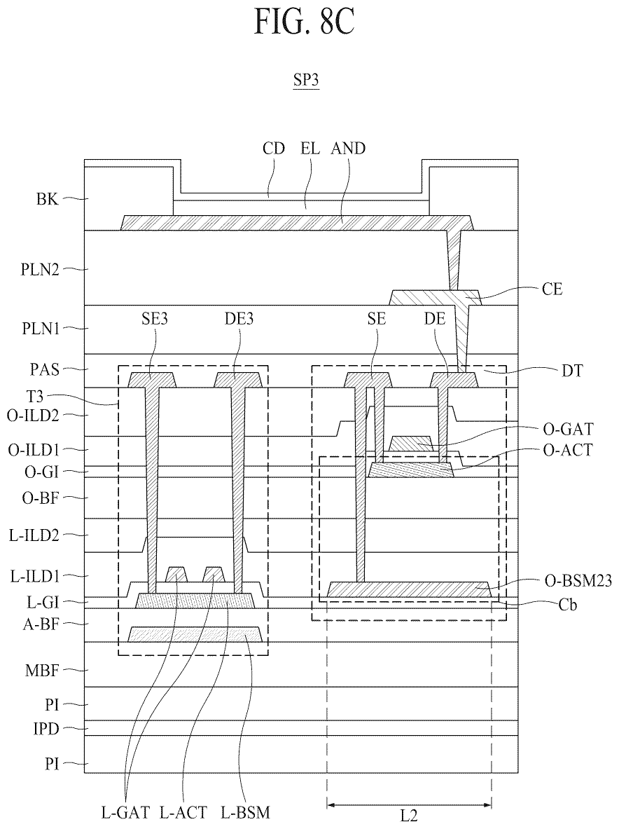

FIG. 7 is a plan view illustrating a layout structure of a pixel circuit in a display apparatus according to one embodiment of the present disclosure. FIGS. 8A to 8C are cross-sectional views illustrating structures of first to third subpixels including the first to third pixel circuits illustrated in FIG. 7, respectively.

The pixel circuits illustrated in FIGS. 7 to 8C have a difference from the pixel circuits illustrated in FIGS. 5 and 6 in that second light shielding electrodes O-BSM21, O-BSM22, and O-BSM23 of each of first to third capacitors Cr, Cg, and Cb of a driving transistors DT in each of pixel circuits PC1, PC2, and PC3 are formed of the same first gate metal layer as the first gate electrode L-GAT, and therefore, descriptions of the overlapping configurations with FIGS. 5 and 6 will be omitted.

Referring to FIGS. 7 to 8C, each of the first to third capacitors Cr, Cg, and Cb of the driving transistors DT in the first to third pixel circuits PC1, PC2, and PC3 of first to third subpixels SP1, SP2, and SP3 may be formed in an overlapping structure of each of the second light shielding electrodes O-BSM21, O-BSM22, and O-BSM23 and the second active layer O-ACT disposed on the second active buffer layer O-BF. The area of each of the second light shielding electrodes O-BSM22 and O-BSM23 of each of the second and third capacitors Cg and Cb may be disposed to be larger than the area of the second light shielding electrode O-BSM21 of the first capacitor Cr. For example, the area of the second light shielding electrode O-BSM23 of the third capacitor Cb may be the largest.

The second light shielding electrode O-BSM21 of the first capacitor Cr may have a first width L1, and each of the second light shielding electrodes O-BSM22 and O-BSM23 of the second and third capacitors Cg and Cb may have a second width L2 greater than the first width L1. According to further embodiment of the disclosure, the second light shielding electrodes O-BSM22 and O-BSM23 of the second and third capacitors Cg and Cb may also have different widths from each other. For example, the width of the second light shielding electrode O-BSM23 of the third capacitors Cb may be the largest.

Accordingly, each of the second and third capacitances of the second and third capacitors Cg and Cb of the second and third pixel circuits PC2 and PC3 may be greater than the first capacitance of the first capacitor Cr of the first pixel circuit PC1.

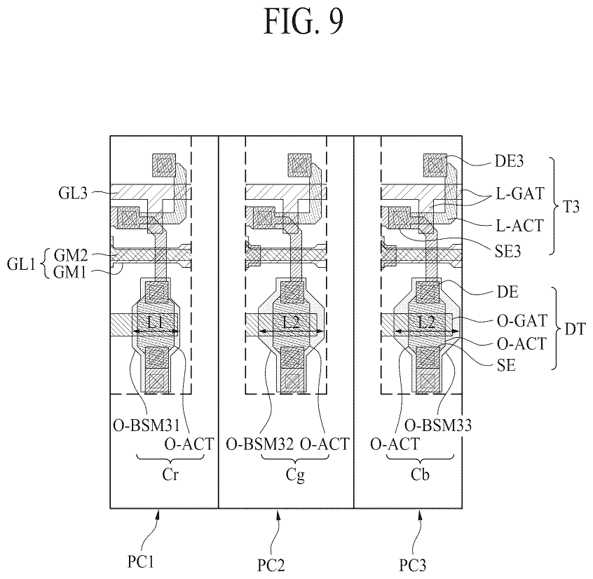

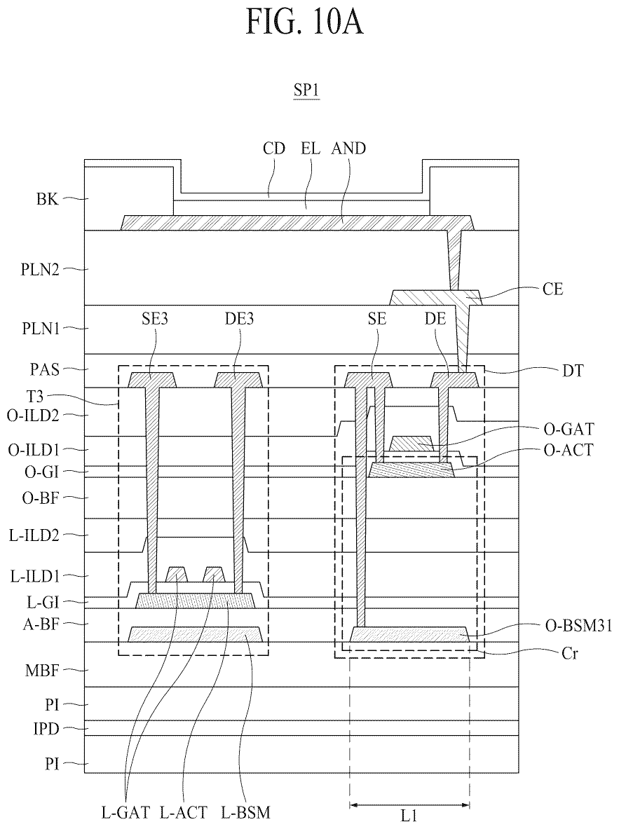

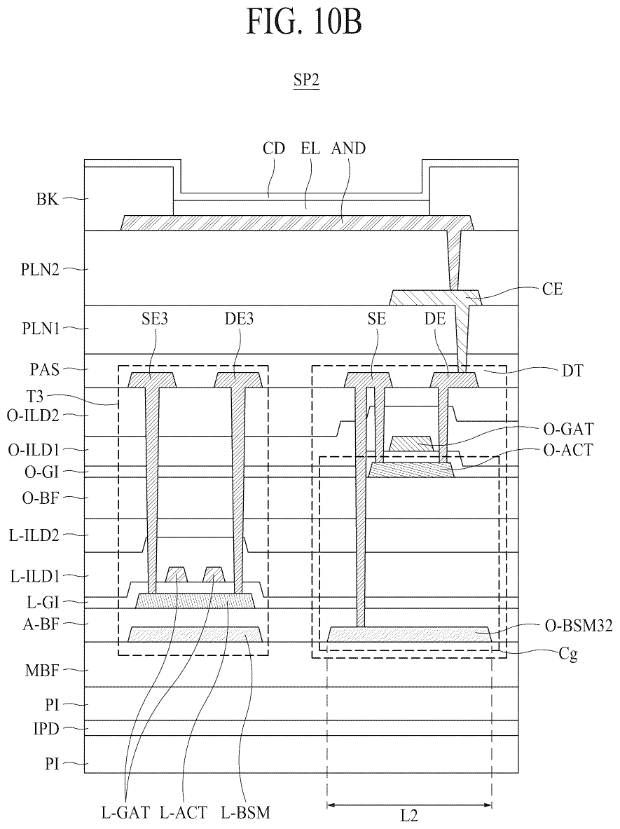

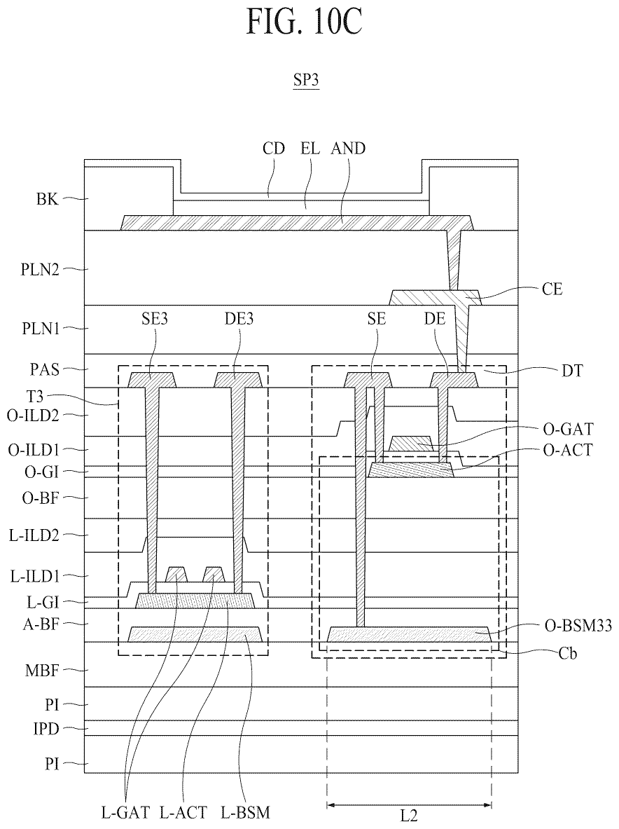

FIG. 9 is a plan view illustrating a layout structure of a pixel circuit in a display apparatus according to one embodiment of the present disclosure. FIGS. 10A to 10C are cross-sectional views illustrating structures of first to third subpixels including the first to third pixel circuits illustrated in FIG. 9, respectively.

The pixel circuits illustrated in FIGS. 9 to 10C have a difference from the pixel circuits illustrated in FIGS. 5 and 6 in that second light shielding electrodes O-BSM31, O-BSM32, and O-BSM33 of first to third capacitors Cr, Cg, and Cb of a driving transistors DT in each of pixel circuits PC1, PC2, and PC3 are formed of the same first light shielding metal layer as the first light shielding electrode L-BSM, and therefore, descriptions of the overlapping configurations with FIGS. 5 and 6 will be omitted.

Referring to FIGS. 9 to 10C, each of the first to third capacitors Cr, Cg, and Cb of the driving transistors DT in the first to third pixel circuits PC1, PC2, and PC3 of the first to third subpixels SP1, SP2, and SP3 may be formed in an overlapping structure of each of the second light shielding electrodes O-BSM31, O-BSM32, and O-BSM33 and the second active layer O-ACT disposed on the second active buffer layer O-BF. The area of each of the second light shielding electrodes O-BSM32 and O-BSM33 of the second and third capacitors Cg and Cb may be disposed to be larger than the area of the second light shielding electrode O-BSM31 of the first capacitor Cr.

The second light shielding electrode O-BSM31 of the first capacitor Cr may have a first width L1, and each of the second light shielding electrodes O-BSM32 and O-BSM33 of the second and third capacitors Cg and Cb may have a second width L2 greater than the first width L1.

Accordingly, each of the second and third capacitances of the second and third capacitors Cg and Cb of the second and third pixel circuits PC2 and PC3 may be greater than the first capacitance of the first capacitor Cr of the first pixel circuit PC1. For example, the capacitances of the second and third capacitors Cg and Cb may be different from each other, and the capacitance of the third capacitor Cb may be the largest.

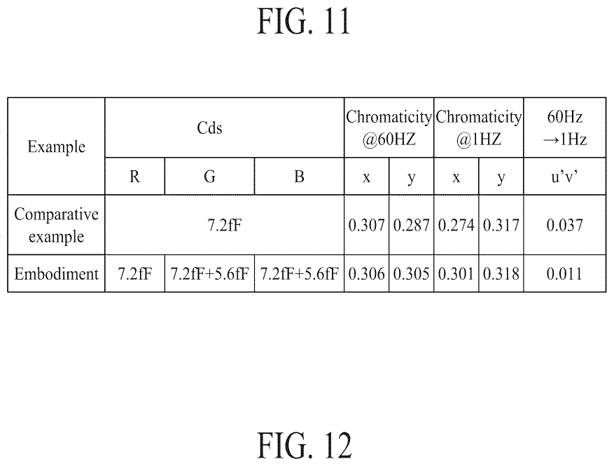

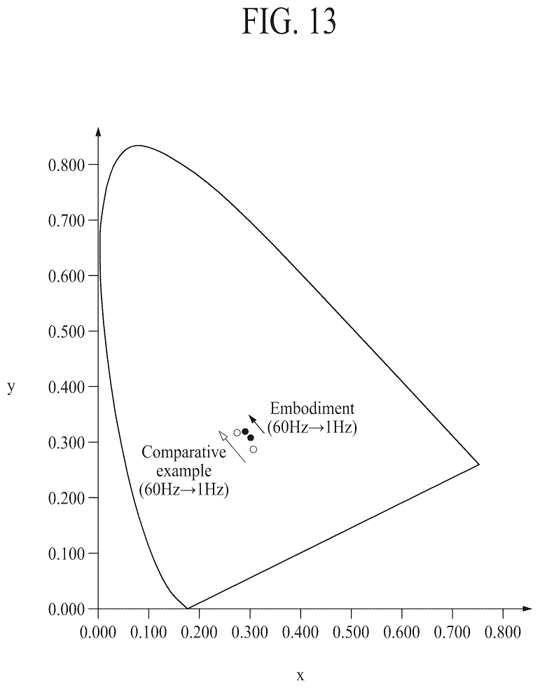

FIG. 11 and FIG. 12 are tables illustrating simulation results of white color coordinate fluctuations when a display apparatus is driven at 1 Hz according to a comparative example and an embodiment, and FIG. 13 is a chromaticity diagram comparing and showing the amount of white color coordinate fluctuations when a display apparatus is driven at 1 Hz according to a comparative example and an embodiment.

Referring to FIGS. 11 to 13, a display apparatus according to a comparative example may correspond to a case where the capacitance between the drain-source electrode of the driving transistor in each of the red, green, and blue subpixels has the same value. A display apparatus according to an embodiment may correspond to a case where a capacitance between a drain-source electrode of a driving transistor in each of the green and blue red subpixels has a larger value than the capacitance between a drain-source electrode of a driving transistor in the red subpixel, as described above.

Referring to FIGS. 11 to 13, it may be seen that the display apparatus according to the comparative example has a relatively large white color coordinate variation (u′v′=0.037), which is the difference between the white color coordinate (x, y=0.307, 0.287) when driven at 60 Hz and the white color coordinate (x, y=0.274, 0.317) when driven at 1 Hz, and thus the white color coordinate fluctuates. As shown in FIG. 12, it may be seen that the white color coordinate variation (u′v′=0.037, 0.033) fluctuated similarly when driven at 60 Hz and 1 Hz in multiple samples (#1, #2) of the display apparatus according to the comparative example.

On the other hand, it may be seen that the white color coordinates (x, y=0.306, 0.305) when the display apparatus is driven at 60 Hz and the white color coordinates (x, y=0.301, 0.318) when the display apparatus is driven at 1 Hz are similar, so that the white color coordinate fluctuation amount (u′v′=0.011) is greatly reduced, thereby preventing or reducing white color coordinate fluctuation. As shown in FIG. 12, it may be seen that the white color coordinate fluctuation amounts (u′v′=0.011, 0.013, 0.011) are similarly greatly reduced when driven at 60 Hz and 1 Hz in multiple samples (#1, #2, #3) of the display apparatus according to one embodiment.

In this way, the display apparatus according to one embodiment of the present disclosure may minimize or reduce the potential fluctuation deviation of the fourth node connected to the light emitting element during low-speed driving by providing different capacitances between the drain-source electrode of the driving transistors for at least two color subpixels among the red, green, and blue subpixels, thereby preventing or reducing fluctuations in white color coordinates.

The display apparatus according to one embodiment of the present disclosure may prevent or reduce white color coordinate fluctuations even when displaying low gray levels by minimizing or reducing potential fluctuation deviations of the fourth node connected to the light emitting element for each red, green, and blue subpixel during low-speed driving.

The display apparatus according to one embodiment of the present disclosure may improve optical quality and achieve low power efficiency by preventing or reducing white color coordinate fluctuations even when displaying low gray levels during low-speed driving.

This disclosure may prevent or reduce color coordinate variation for each subpixel by including different capacitances between the drain and source of driving transistors for each subpixel with different characteristics without adding a mask process.

The above-described feature, structure, and effect of the present disclosure are included in at least one embodiment of the present disclosure, but are not limited to only one embodiment. Furthermore, the feature, structure, and effect described in at least one embodiment of the present disclosure may be implemented through combination or modification of other embodiments by those skilled in the art. Therefore, content associated with the combination and modification should be construed as being within the scope of the present disclosure.

It will be apparent to those skilled in the art that various substitutions, modifications, and variations are possible within the scope of the present disclosure without departing from the spirit and scope of the present disclosure. Therefore, the scope of the present disclosure includes those represented by the following claims, and all changes or modifications derived from the meaning, range and equivalent concept of the claims should be interpreted as being included in the scope of the present disclosure.

The various embodiments described above may be combined to provide further embodiments. Aspects of the embodiments may be modified, if necessary to employ concepts of the various embodiments to provide yet further embodiments.

These and other changes may be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A display apparatus, comprising:
a first subpixel including a first light emitting element configured to emit light of a first color, a first driving transistor configured to drive the first light emitting element, and a first capacitor disposed between a drain electrode and a source electrode of the first driving transistor; and
a second subpixel including a second light emitting element configured to emit light of a second color, a second driving transistor configured to drive the second light emitting element, and a second capacitor disposed between a drain electrode and a source electrode of the second driving transistor,
wherein a capacitance of the first capacitor is different from a capacitance of the second capacitor.

2. The display apparatus of claim 1 further comprising:
a third subpixel including a third light emitting element configured to emit light of a third color, a third driving transistor configured to drive the third light emitting element, and a third capacitor disposed between a drain electrode and a source electrode of the third driving transistor,
wherein a capacitance of the third capacitor is different from the capacitance of at least one of the first and second capacitors.

3. The display apparatus of claim 2, wherein:
the first light emitting element is configured to emit a red light;
the second light emitting element is configured to emit a green light;
the third light emitting element is configured to emit a blue light;
among the first, second and third light emitting elements, an emission area of the first light emitting element is the smallest; and
the capacitances of the second and third capacitors are greater than the capacitance of the first capacitor.

4. The display apparatus of claim 2, wherein:
the first subpixel includes a first pixel circuit configured to drive the first light emitting element;
the second subpixel includes a second pixel circuit configured to drive the second light emitting element;
the third subpixel includes a third pixel circuit configured to drive the third light emitting element;
each of the first, second, and third pixel circuits includes a polysilicon transistor and an oxide transistor; and
each of the first, second, and third driving transistors includes the oxide transistor.

5. The display apparatus of claim 4,
wherein the polysilicon transistor comprises:
a first light shielding electrode disposed on a multi-buffer layer on a substrate;
a first active layer disposed on a first active buffer layer covering the first light shielding electrode;
a first gate electrode disposed on a first gate insulating layer covering the first active layer; and
source and drain electrodes disposed on a plurality of insulating layers covering the first gate electrode and connected to the first active layer through first and second contact holes respectively penetrating the plurality of insulating layers.

6. The display apparatus of claim 5,
wherein each of the first, second, and third driving transistors comprises:
a second light shielding electrode;
a second active layer disposed on a second active buffer layer covering the second light shielding electrode;
a second gate electrode disposed on a second gate insulating layer covering the second active layer; and
source and drain electrodes disposed on a plurality of second interlayer insulating layers covering the second gate electrode and connected to the second active layer through third and fourth contact holes respectively penetrating the plurality of second interlayer insulating layers.

7. The display apparatus of claim 6, wherein:
each of the first, second, and third capacitors is provided by an overlap between the second light shielding electrode and the second active layer; and
an area of the second light shielding electrode of each of the second and third capacitors is greater than an area of the second light shielding electrode of the first capacitor.

8. The display apparatus of claim 6,
wherein the second light shielding electrode is disposed on a plurality of first interlayer insulating layers disposed over the first gate electrode.

9. The display apparatus of claim 6,
wherein the second light shielding electrode is disposed on a same layer as the first gate electrode.

10. The display apparatus of claim 6,
wherein the second light shielding electrode is disposed on a same layer as the first light shielding electrode.

11. The display apparatus of claim 3, wherein:
an emission area of the third light emitting element is the largest and the capacitance of the third capacitor is the largest.

12. The display apparatus of claim 7, wherein:
a width of the second light shielding electrode of each of the second and third capacitors is greater than a width of the second light shielding electrode of the first capacitor.
